(19) United States
(12) Patent Application Publication
(10) Pub. No.: US 2016/0379969 A1
(43) Pub. Date: Dec. 29, 2016

(54) Patterned Wafer and Method of Making the Same

(71) Applicant: Wafer Mems Co., LTD., Miaoli County (TW)

(72) Inventors: Min-Ho Hsiao, Miaoli County (TW); Pang-Yen Lee, Miaoli County (TW); Yen-Hao Tseng, Miaoli County (TW)

(21) Appl. No.: 15/152,885

(22) Filed: May 12, 2016

(30) Foreign Application Priority Data
Jun. 25, 2015 (TW) 104120520

(51) Int. Cl. H01L 27/01; H01L 21/70; H01L 49/02

(52) U.S. Cl. CPC H01L 27/013; H01L 28/10; H01L 21/705

(57) ABSTRACT

A patterned wafer used for production of passive-component chip bodies includes a peripheral end portion and at least one passive-component unit that including a connecting portion, a breaking line, and a plurality of spaced apart chip bodies. The connecting portion is connected to the peripheral end portion and is spaced apart from the chip bodies by a tab-accommodating space along a first direction. The breaking line has a plurality of connecting tabs that are spaced apart from one another and that are disposed in the tab-accommodating space. Each of the connecting tabs interconnects the connecting portion and a respective one of the chip bodies. A method for making the patterned wafer is also disclosed.

### CROSS-REFERENCE TO RELATED APPLICATION

This application claims priority of Taiwanese Application No. 104120520, filed on Jun. 25, 2015.

### FIELD

The disclosure relates to a patterned wafer and a method of making the same, more particularly to a patterned wafer including a peripheral end portion and at least one passive-component unit.

### BACKGROUND

There are three types of inductors, namely thin film type inductors, multilayered type inductors, and wire wound type inductors, which are commercially available.

TW patent application publication No. 201440090 A discloses a multi layered type inductor (as shown in FIG. 1) and a method of making the same.

The method of making the multilayered type inductor includes the steps of: laminating a first circuit plate 110, a second circuit plate 120, a third circuit plate 130 and a fourth circuit plate 140 (see FIG. 2A); attaching an assembly of a supporting film 150 and a bonding pad circuit 160 to the first circuit plate 110 (see FIG. 2B); transferring the bonding pad circuit 160 from the supporting film 150 to the first circuit plate 110 (see FIG. 2C); removing the supporting film 150 from the bonding pad circuit 160 (see FIG. 2D); sintering the first, second, third and fourth circuit plates 110, 120, 130, 140 and the bonding pad circuit 160 so as to form a multilayered substrate 100 (see FIG. 2E); and scribing the multilayered substrate 100 using a scriber 170 (see FIG. 2F), so that the multilayered substrate 100 can be broken into a plurality of multilayered type inductors 10 (see FIG. 1).

Referring to FIG. 1, each of the first, second, third and fourth circuit plates 110, 120, 130, 140 includes a respective one of non-magnetic bodies 111, 121, 131, 141 and a respective one of first, second, third and fourth circuit patterns 112, 122, 132, 142. Formation of the first, second, third and fourth circuit plates 110, 120, 130, 140 requires numerous steps (a total of at least 13 steps), including punching each non-magnetic body 111, 121, 131, 141 to form holes therein, filling conductive paste in the holes, forming the first, second, third and fourth circuit patterns 112, 122, 132, 142 and sintering, before laminating the first, second, third and fourth circuit plates 110, 120, 130, 140.

The aforesaid method is relatively complicated, and the bonding strength between the first, second, third and fourth circuit patterns 112, 122, 132, 142 may be insufficient. There is still a need to simplify both the structure of the multilayered type inductor and the method of making the same.

### SUMMARY

Therefore, an object of the disclosure is to provide a patterned wafer that may alleviate the drawback of the prior art.

Another object of the disclosure is to provide a method of making a patterned wafer that may alleviate the drawback of the prior art.

According to one aspect of the disclosure, there is provided a patterned wafer used for production of passive-component chip bodies. The patterned wafer includes a peripheral end portion, and at least one passive-component unit that includes a connecting portion, a breaking line, and a plurality of spaced apart chip bodies.

The connecting portion is connected to the peripheral end portion, and is spaced apart from the chip bodies by a tab-accommodating space along a first direction. The breaking line has a plurality of connecting tabs that are spaced apart from one another and that are disposed in the tab-accommodating space.

Each of the connecting tabs interconnects the connecting portion and a respective one of the chip bodies.

According to another aspect of the disclosure, there is provided a method of making a patterned wafer that is used for production of passive-component chip bodies. The method includes:

forming at least one patterned photoresist layer on a wafer such that the wafer has an etched portion exposed from the patterned photoresist layer, the patterned photoresist layer having a peripheral end part and at least one passive-component-defining unit, the passive-component-defining unit having a connecting part, a plurality of breaking-line-defining protrusions, and a plurality of chip-defining parts;

etching the etched portion so as to pattern the wafer; and

removing the patterned photoresist layer from the patterned wafer, such that the patterned wafer has a peripheral end portion and at least one passive-component unit that includes a connecting portion, a breaking line, and a plurality of spaced apart chip bodies, the connecting portion being connected to the peripheral end portion, the breaking line having a plurality of connecting tabs that are spaced apart from one another, each of the connecting tabs being disposed between and interconnecting the connecting portion and a respective one of the chip bodies.

### BRIEF DESCRIPTION OF THE DRAWINGS

Other features and advantages of the disclosure will become apparent in the following detailed description of the embodiment with reference to the accompanying drawings, of which:

FIG. 1 is an exploded perspective view of a multilayered type inductor disclosed in TW patent application publication No. 201440090 A;

FIGS. 2A to 2F are sectional views illustrating consecutive steps of a method of making the multilayered type inductor of FIG. 1;

FIG. 3 is a fragmentary top view illustrating the first embodiment of a patterned wafer according to the disclosure;

FIG. 4 is a perspective view illustrating a passive-component unit included in the first embodiment;

FIG. 5 is a perspective view illustrating a passive-component unit included in the second embodiment of a patterned wafer according to the disclosure;

FIG. 6 is a perspective view illustrating a passive-component unit included in the third embodiment of a patterned wafer according to the disclosure;

FIG. 7 is a sectional view taken along lines VII-VII of FIG. 8;

FIG. 8 is a partially sectional view of an inductor made from the first embodiment of a patterned wafer according to the disclosure;

FIG. 9 is a perspective view illustrating a passive-component unit included in the fourth embodiment of a patterned wafer according to the disclosure;

FIG. 10 is a perspective view illustrating a passive-component unit included in the fifth embodiment of a patterned wafer according to the disclosure;

FIG. 11 is a fragmentary top view illustrating a patterned photoresist layer used in step S1 of a method of making the patterned wafer according to the disclosure;

FIG. 12 is an enlarge view of an encircled portion in FIG. 11;

FIG. 13 is a sectional view taken along lines XIII-XIII of FIG. 12;

FIG. 14 is a fragmentary top view illustrating step S2 of the method of making a patterned wafer according to the disclosure;

FIG. 15 is a sectional view taken along line XV-XV of FIG. 14;

FIG. 16 is a fragmentary top view illustrating step S3 of the method of making a patterned wafer according to the disclosure; and

FIG. 17 is a fragmentary top view illustrating step S4 of the method of making a patterned wafer according to the disclosure.

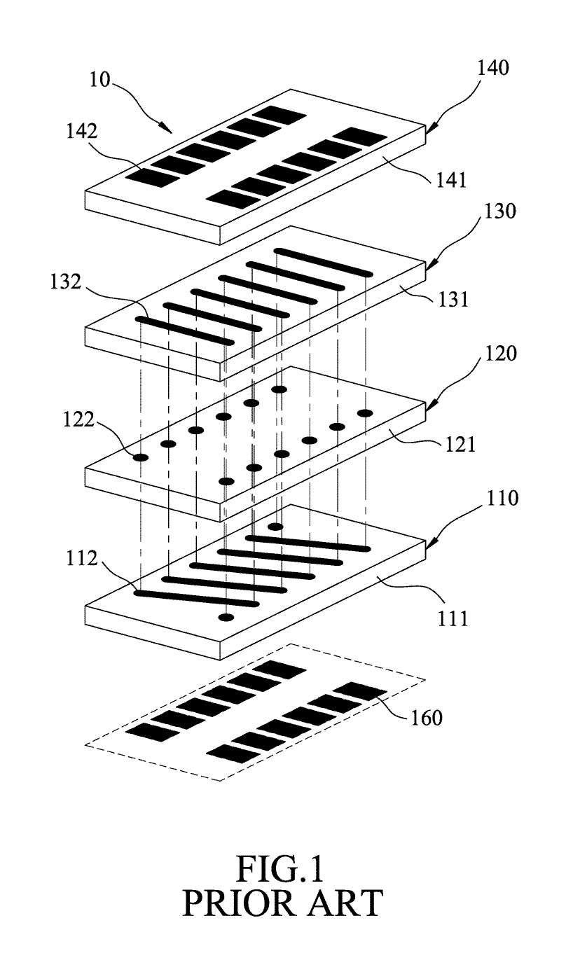

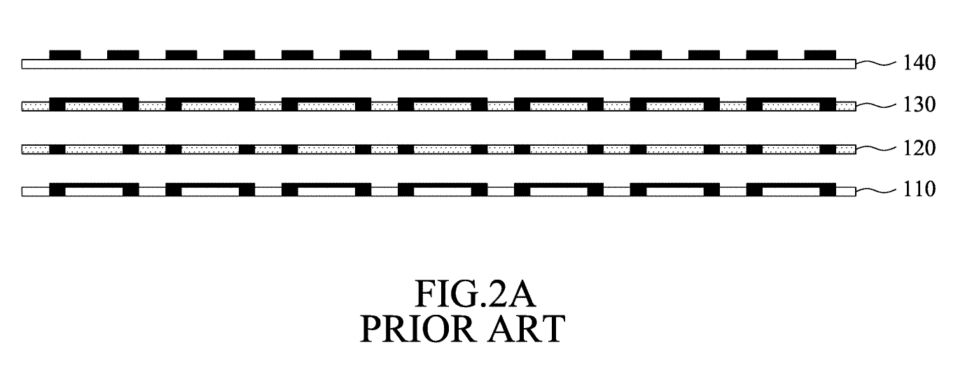

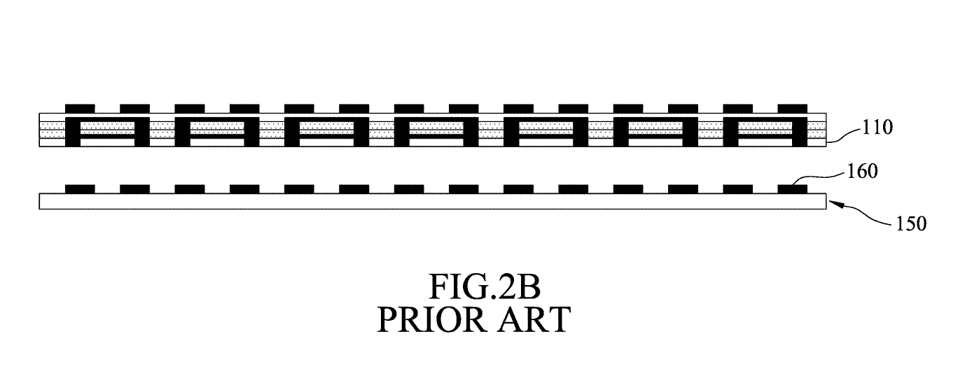

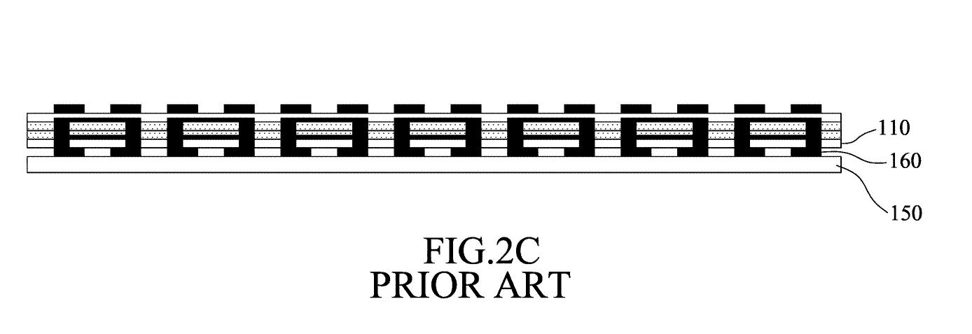

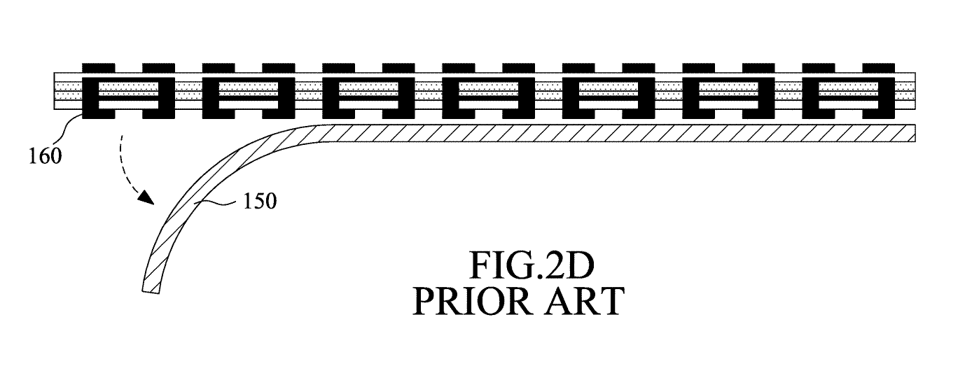

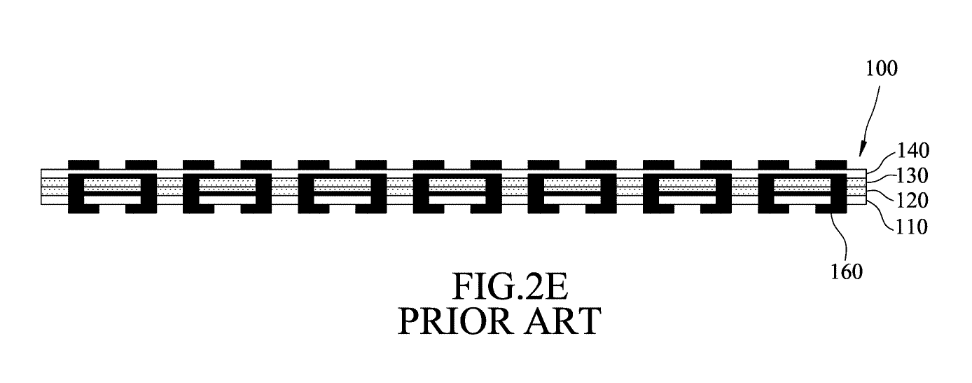

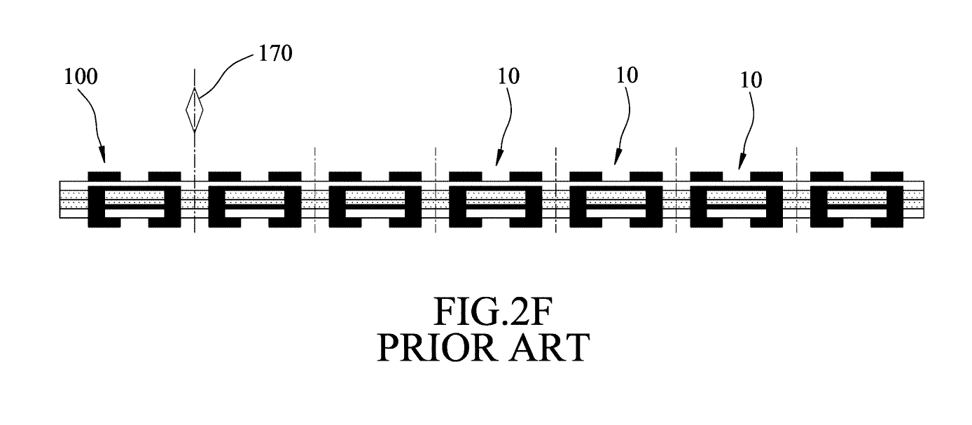

### DETAILED DESCRIPTION

It may be noted that like elements are denoted by the same reference numerals throughout the disclosure.

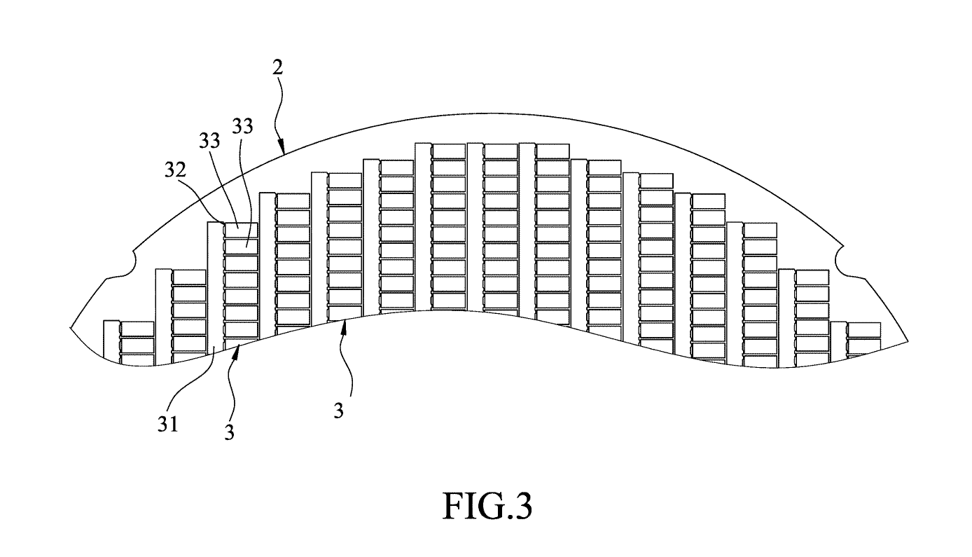

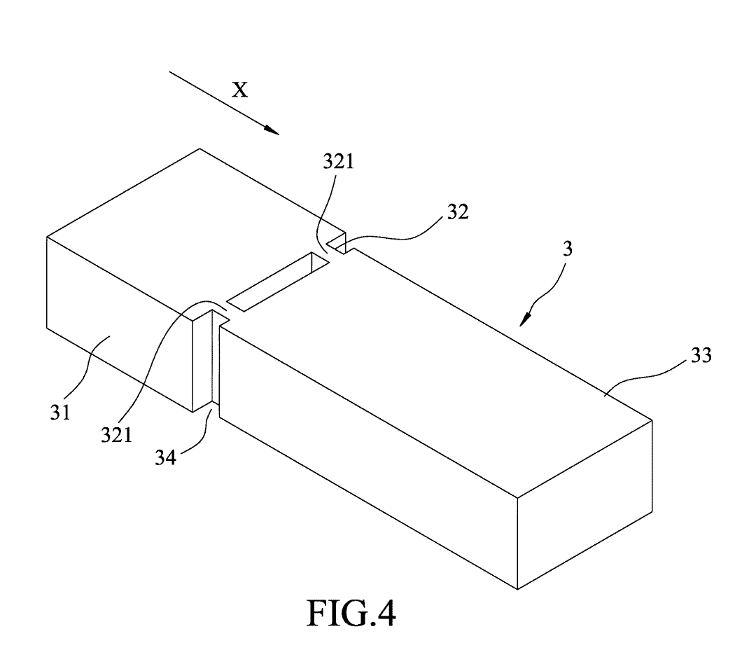

FIGS. 3 and 4 illustrate the first embodiment of a patterned wafer used for production of passive-component chip bodies according to the disclosure. The patterned wafer includes a peripheral end portion 2 and at least one passive-component unit 3 that including a connecting portion 31, a breaking line 32, and a plurality of spaced apart chip bodies 33. Since each of the chip bodies 33 is a single piece formed from a wafer (not shown), it has a higher mechanical strength than that of the conventional multilayered type inductor.

The connecting portion 31 is connected to the peripheral end portion 2, and is spaced apart from the chip bodies 33 by a tab-accommodating space 34 along a first direction (X). The breaking line 32 has a plurality of connecting tabs 321 that are spaced apart from one another and that are disposed in the tab-accommodating space 34. Each of the connecting tabs 321 interconnects the connecting portion 31 and a corresponding one of the chip bodies 33. In this embodiment, two of the connecting tabs 321 interconnect the connecting portion 31 and the corresponding one of the chip bodies 33. The patterned wafer is a single piece of a magnetic material or a non-magnetic material.

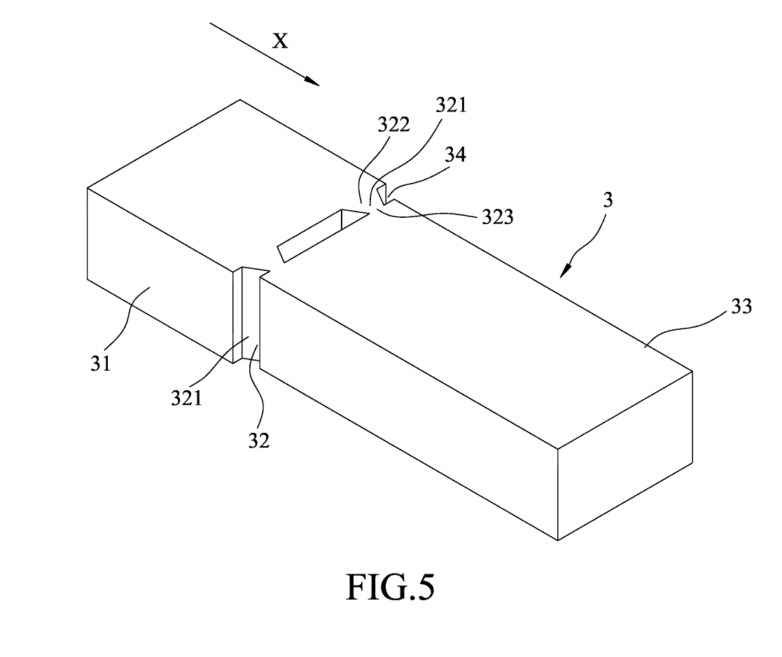

FIG. 5 illustrates the second embodiment of a patterned wafer according to the disclosure. The patterned wafer of the second embodiment has a structure similar to that of the first embodiment, except that each of the connecting tabs 321 has a first end 322 connected to the connecting portion 31 and a second end 323 connected to the corresponding one of the chip bodies 33, and is reduced in width from the first end 322 toward the second end 323 along the first direction (X).

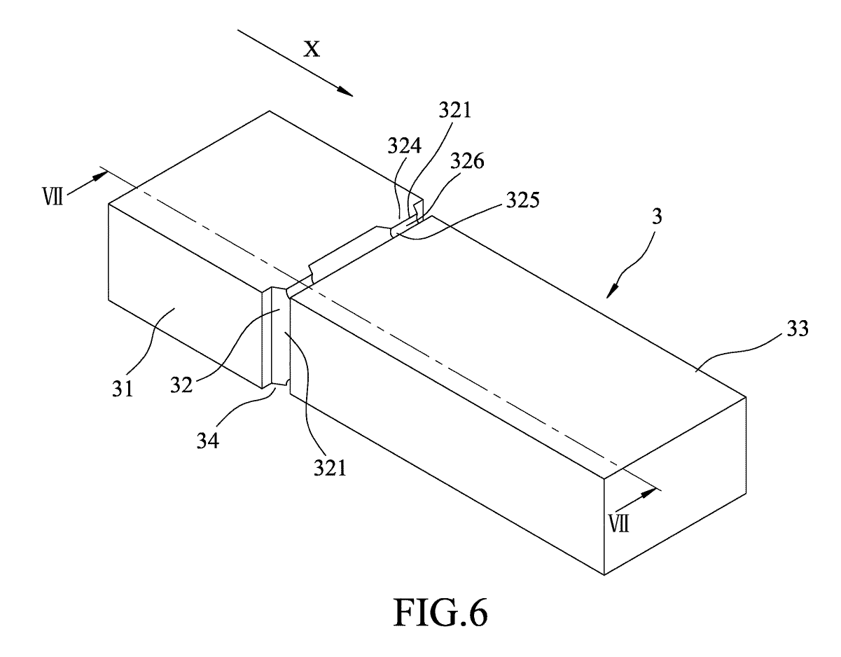

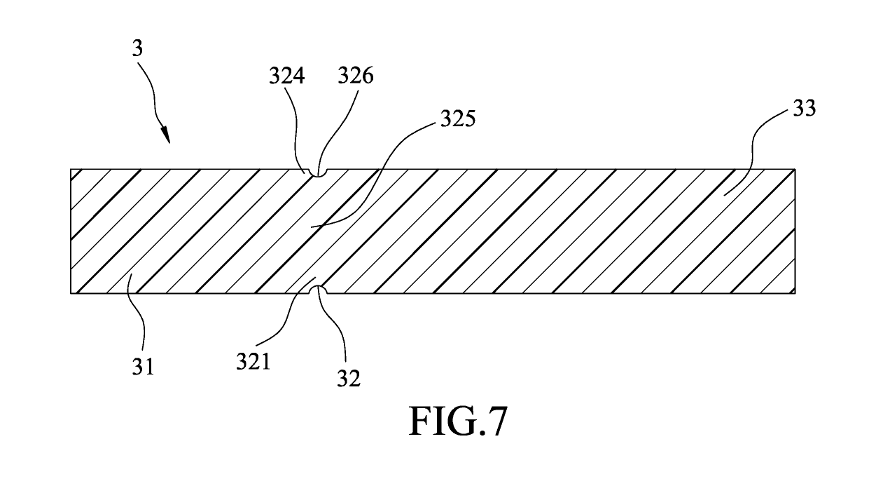

FIGS. 6 and 7 illustrate the third embodiment of a patterned wafer according to the disclosure. The patterned wafer of the third embodiment has a structure similar to that of the first embodiment, except that each of the connecting tabs 321 has a base segment 324 protruding from the connecting portion 31 in the first direction (X), and a neck segment 325 extending in the first direction (X) from the base segment 324 to the corresponding one of the chip bodies 33 and cooperating with the base segment 324 and the corresponding one of the chip bodies 23 to define at least one recess 326 thereamong. In certain embodiment, the base segment 324 is reduced in width from the first end 322 toward the second end 323 along the first direction (X).

In certain embodiments, the patterned wafer is made from a silicon-based material or a metallic material. The silicon-based material is selected from the group consisting of quartz, silicon, silicon carbide (SiC) and silicon nitride (Si₃N₄).

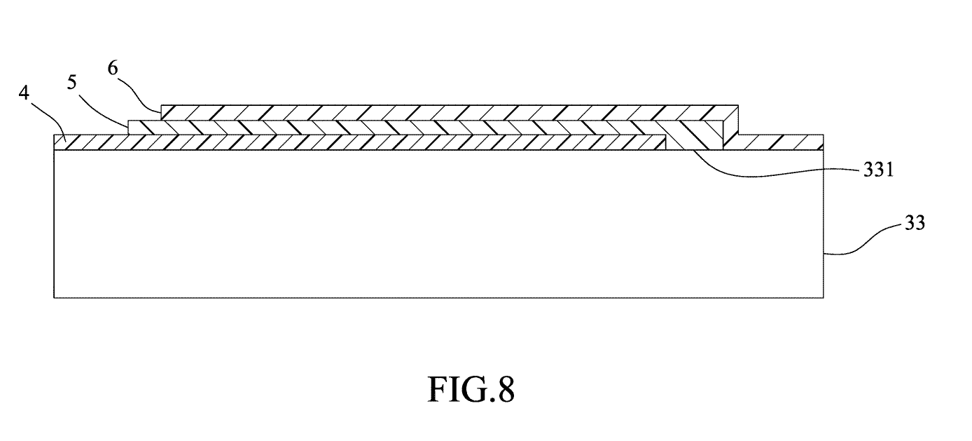

In certain embodiments, the patterned wafer of the disclosure may be made using MEMS fabrication processes. Each of the chip bodies 33 maybe used for making a passive component by forming a circuit thereon. For example, as shown in FIG. 8, the method of making an inductor may include forming in sequence a first electrode layer 4, a dielectric layer 5 and a second electrode layer on a surface 331 of the chip body 33 of the passive-component unit.

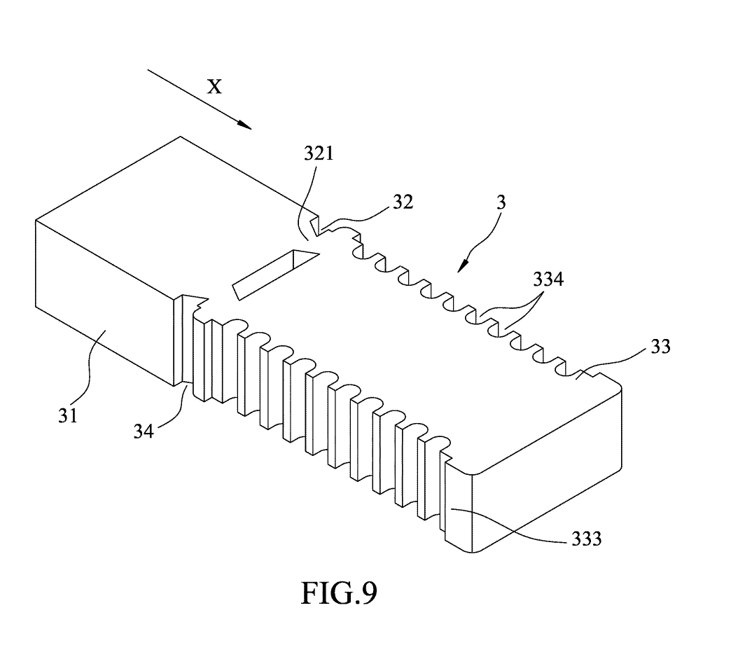

Referring to FIG. 9, a fourth embodiment of the patterned wafer according to the disclosure differs from the second embodiment in that each of the chip bodies 33 of the fourth embodiment further includes a plurality of spaced apart notches 334 that are indented inwardly from side surfaces 333 thereof. A coil (not shown) may extend into and through the notches 334 to surround the chip body 33 to form a passive component, such as an inductor.

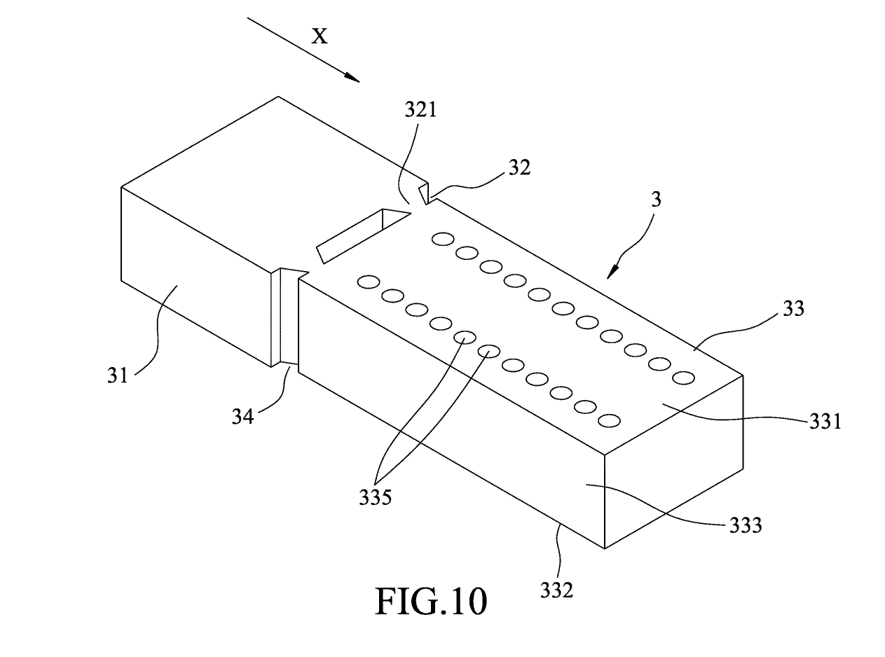

Referring to FIG. 10, a fifth embodiment of the patterned wafer according to the disclosure differs from the second embodiment in that each of the chip bodies 33 of the fifth embodiment further includes a plurality of spaced apart holes 335 that extend through a top surface 331 and a bottom surface 332 thereof and that are disposed between the side surfaces 333. A coil may extend into and through the holes 335 to substantially surround the chip body 33 to form a passive component, such as an inductor.

The following description illustrates a method of making the patterned wafer of the embodiment of the disclosure, and should not be construed as limiting the scope of the disclosure. The method includes the steps of S1 to S4.

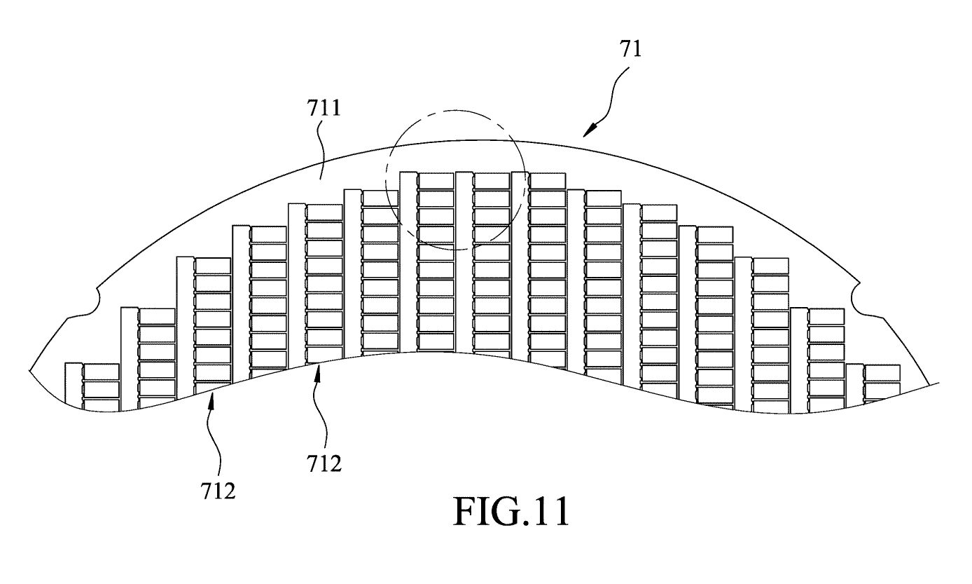

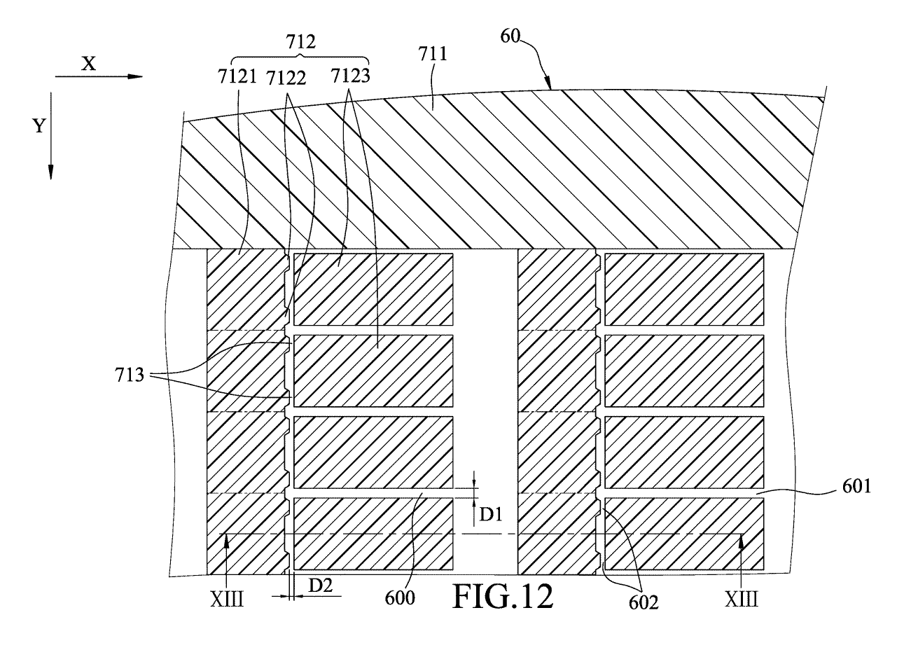

In step S1 (see FIGS. 11, 12 and 13), at least one patterned photoresist layer 71 is formed on a wafer 60, such that the wafer 60 has an etched portion 600 exposed from the patterned photoresist layer 71. The patterned photoresist layer 71 has a peripheral end part 711 and at least one passive-component-defining unit 712. The passive-component-defining unit 712 has a connecting part 7121, a plurality of breaking-line-defining protrusions 7122, and a plurality of chip-defining parts 7123.

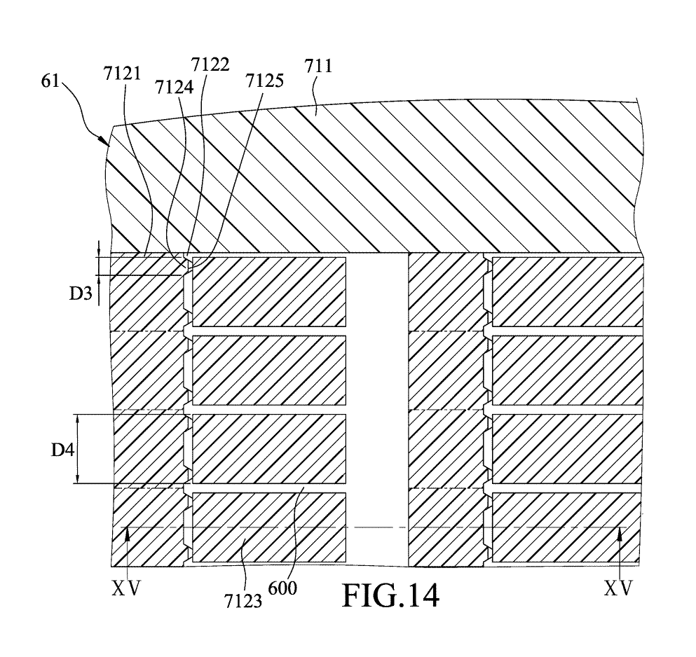

Moreover, each of the breaking-line-defining protrusions 7122 is aligned with a respective one of the chip-defining parts 7123 in a first direction (X) and having a width (D3) smaller than a width (D4) of the respective one of the chip-defining parts 7123 in a second direction (Y) that is perpendicular to the first direction (X) (see FIG. 14).

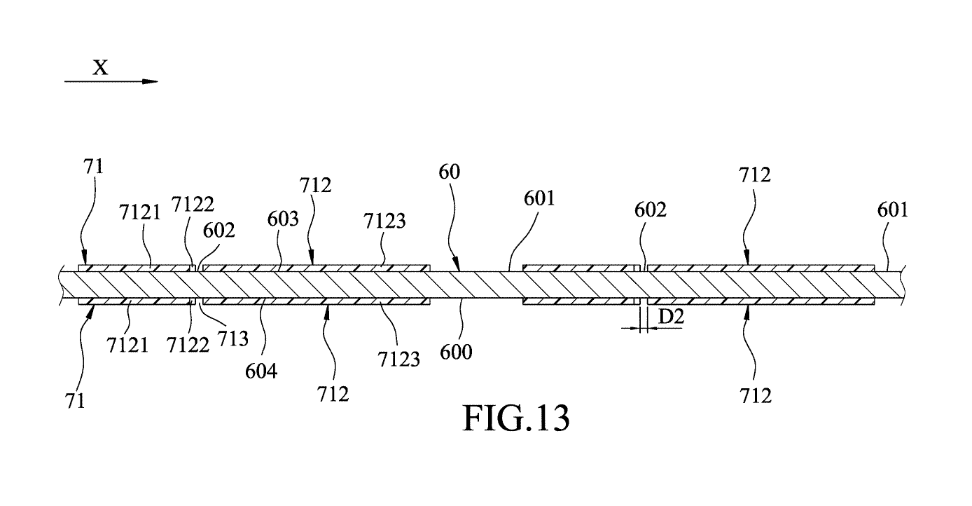

In certain embodiment, the wafer 60 has top and bottom surfaces 603, 604, each of which is formed with the patterned photoresist layer 71, and the patterned photoresist layers 71 formed on the top and bottom surfaces are symmetrical to each other (see FIG. 13).

It should be noted that each of the breaking-line-defining protrusions 7122 may be connected to or spaced apart from a respective one of the chip-defining parts 7123.

In this embodiment, each of the breaking-line-defining protrusions 7122 is spaced apart from a respective one of the chip-defining parts 7123. As such, the etched portion of the wafer 60 has a plurality of to-be-fully-etched regions 601 that are exposed from the respective patterned photoresist layer 71, and a plurality of to-be-partially-etched regions 602 that are exposed from the respective patterned photoresist layer 71 (see FIG. 14). Each of the breaking-line-defining protrusions 7122 is spaced apart from a respective one of the chip-defining parts 7123 by a gap 713. The gaps 713 which are defined by the breaking-line-defining protrusions 7122 and the chip-defining parts 7123 are respectively aligned with the to-be-partially-etched regions 602 so as to expose the to-be-partially-etched regions 602 therefrom. Since the to-be-partially-etched regions 602 have a width (D2) in the first direction that is significantly less than a width (D1) of the to-be-fully-etched regions 601 in the second direction, the to-be-partially-etched regions 602 have an etching rate lower than that of the to-be-fully-etched regions 601.

As mentioned above, the patterned photoresist layers 71 formed on the top and bottom surfaces 603, 604 are symmetrical to each other, so that the to-be-partially-etched regions 602 and the to-be-fully-etched regions 601 of the top surface 603 are symmetrical to the to-be-partially-etched regions 602 and the to-be-fully-etched regions 601 of the bottom surface 604.

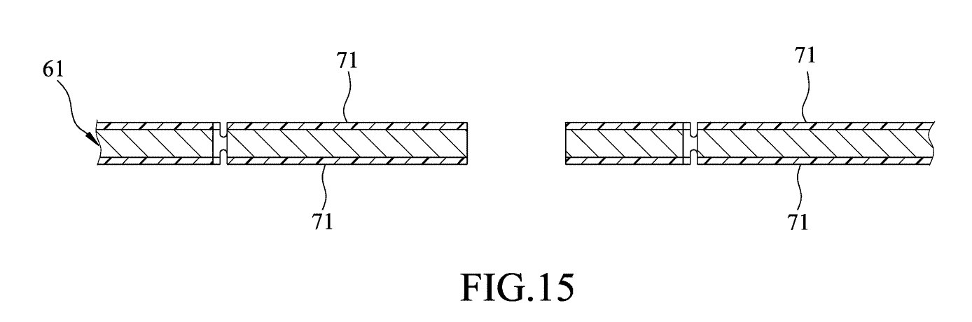

In step S2, the etched portion 600 is etched so as to pattern the wafer 60. Specifically, as shown in FIGS. 14 and 15, the to-be-partially-etched regions 602 and the to-be-fully-etched regions 601 of the top and bottom surfaces 603, 604 of the wafer 60 are simultaneously etched, such that the wafer 60 is patterned so as to form a patterned wafer 61.

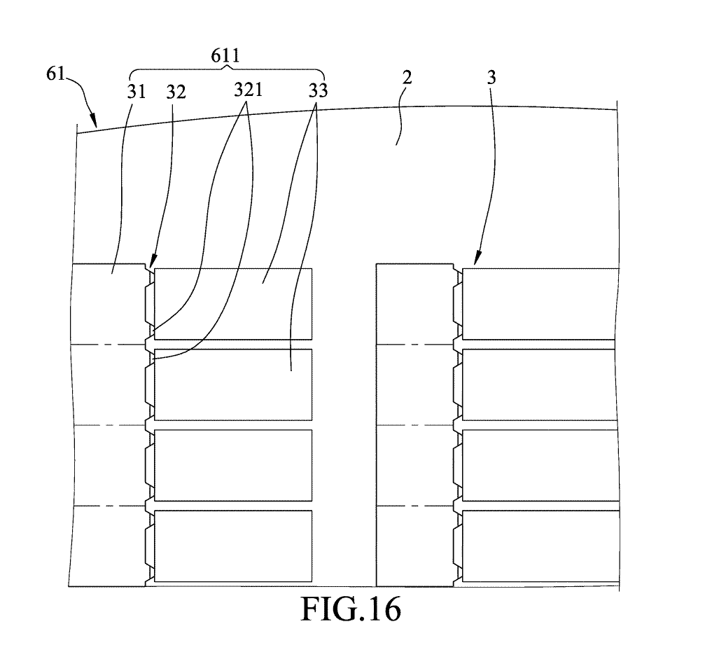

In step S3 (see FIG. 16), all of the patterned photoresist layers 71 are removed from the patterned wafer 61. The patterned wafer 61 has a peripheral end portion 2 and at least one passive-component unit 3 that includes a connecting portion 31, a breaking line 32, and a plurality of spaced apart chip bodies 33. The connecting portion 31 is connected to the peripheral end portion 2. The breaking line 32 has a plurality of connecting tabs 321 that are spaced apart from one another. Each of the connecting tabs 321 is disposed between and interconnects the connecting portion 31 and a corresponding one of the chip bodies 33. In this embodiment, two of the connecting tabs 321 interconnect the connecting portion 31 and the corresponding one of the chip bodies 33. In this embodiment, the passive-component unit 3 has a structure similar to that shown in FIG. 6.

The shape of the connecting tabs 321 thus formed can be controlled based on actual requirements by varying the shape of the breaking-line-defining protrusions 7122. In one embodiment, referring back to FIG. 14, each of the breaking-line-defining protrusions 7122 has a first end 7124 connected to the connecting part 7121 and a second end 7125 disposed adjacent to the respective one of the chip-defining parts 7123 and opposite to the first end 7124 in the first direction (X), and is reduced in width (D3) along the first direction (X) from the first end 7124 toward the second end 7125.

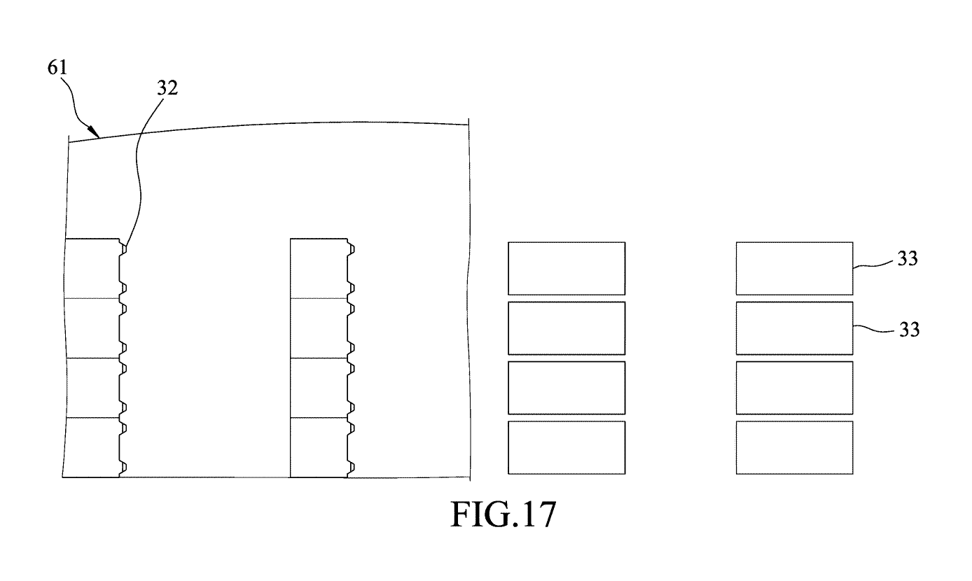

In step S4, (see FIG. 17), the patterned wafer 61 is broken along the breaking line 32 by applying an external force thereto so as to separate the chip bodies 33 from the connecting portion 31. Alternatively, the patterned wafer 61 may be broken along the breaking line using a scriber (not shown) or using etching techniques.

In certain embodiments, the wafer is made from a silicon-based material or a metallic material. The silicon-based material is selected from the group consisting of quartz, silicon, silicon carbide (SiC) and silicon nitride (Si₃N₄). When the wafer is made from a silicon based material, the method may further include a step of forming a metallic protective layer (not shown) on the wafer before formation of the patterned photoresist layer 71, and the patterned photoresist layer 71 is formed on the metallic protective layer.

In summary, the method of the present disclosure may be advantageous over the prior art in reducing the steps of making the passive component.

While the present disclosure has been described in connection with what are considered the exemplary embodiments, it is understood that this disclosure is not limited to the disclosed embodiments but is intended to cover various arrangements included within the spirit and scope of the broadest interpretation so as to encompass all such modifications and equivalent arrangements.

What is claimed is:

1. A patterned wafer used for production of passive-component chip bodies, comprising:
a peripheral end portion; and
at least one passive-component unit that includes a connecting portion, a breaking line, and a plurality of spaced apart chip bodies, said connecting portion being connected to said peripheral end portion and being spaced apart from said chip bodies by a tab-accommodating space along a direction, said breaking line having a plurality of connecting tabs that are spaced apart from one another and that are disposed in said tab-accommodating space;
wherein each of said connecting tabs interconnects said connecting portion and a respective one of said chip bodies.

2. The patterned wafer of claim 1, wherein each of said connecting tabs has a first end connected to said connecting portion and a second end connected to the respective one of said chip bodies, and is reduced in width from said first end toward said second end along said direction.

3. The patterned wafer of claim 1, wherein each of said connecting tabs has abase segment that protrudes from said connecting portion in said direction, and a neck segment that extends in said direction from said base segment to the respective one of said chip bodies and that cooperates with said base segment and the respective one of said chip bodies to define at least one recess thereamong.

4. The patterned wafer of claim 1, wherein said patterned wafer is made from a silicon-based material or a metallic material, said silicon-based material being selected from the group consisting of quartz, silicon, silicon carbide and silicon nitride.

5. A method of making a patterned wafer that is used for production of passive-component chip bodies, comprising:
forming at least one patterned photoresist layer on a wafer such that the wafer has an etched portion exposed from the patterned photoresist layer, the patterned photoresist layer having a peripheral end part and at least one passive-component-de fining unit, the passive-component-defining unit having a connecting part, a plurality of breaking-line-defining protrusions, and a plurality of chip-defining parts;
etching the etched portion so as to pattern the wafer; and
removing the patterned photoresist layer from the patterned wafer, such that the patterned wafer has a peripheral end portion and at least one passive-component unit that includes a connecting portion, a breaking line, and a plurality of spaced apart chip bodies, the connecting portion being connected to the peripheral end portion, the breaking line having a plurality of connecting tabs that are spaced apart from one another, each of the connecting tabs being disposed between and interconnecting the connecting portion and a respective one of the chip bodies.

6. The method of claim 5, wherein each of the breaking-line-defining protrusions being aligned with a respective one of the chip-defining parts in a first direction and having a width smaller than that of the respective one of the chip-defining parts in a second direction that is perpendicular to the first direction.

7. The method of claim 5, wherein the wafer has top and bottom surfaces, each of which is formed with the patterned photoresist layer, the patterned photoresist layers formed on the top and bottom surfaces being symmetrical to each other.

8. The method of claim 5, wherein the etched portion of the wafer has a plurality of to-be-fully-etched regions and a plurality of to-be-partially-etched regions, each of the breaking-line-defining protrusions being spaced apart from the respective one of the chip-defining parts by a gap, the gaps defined by the breaking-line-defining protrusions and the chip-defining parts being aligned with the to-be-partially-etched regions so as to expose the to-be-partially-etched regions therefrom, each of the to-be-partially-etched region having an etching rate lower than that of each of the to-be-fully-etched region.

9. The method of claim 8, wherein the wafer has top and bottom surfaces, each of which is formed with the patterned photoresist layer, the patterned photoresist layers formed on the top and bottom surfaces being symmetrical to each other, the to-be-partially-etched regions and the to-be-fully-etched regions of each of the patterned photoresist layers being simultaneously etched.

10. The method of claim 8, wherein each of the breaking-line-defining protrusions has a first end connected to the connecting part and a second end disposed adjacent to the respective one of the chip-defining parts and opposite to the first end in a direction, and is reduced in width along the direction from the first end toward the second end.

11. The method of claim 5, further comprising breaking the patterned wafer along the breaking line so as to separate the chip bodies from the connecting portion.

12. The method of claim 5, wherein the wafer is made from a silicon-based material or a metallic material, the silicon-based material being selected from the group consisting of quartz, silicon, silicon carbide and silicon nitride.

13. The method of claim 5, wherein the wafer is made from a silicon-based material, the method further comprising forming a metallic protective layer on the wafer before formation of the patterned photoresist layer, the patterned photoresist layer being formed on the metallic protective layer.
